(19) United States
(12) Patent Application Publication
(10) Pub. No.: US 2026/0296957 A1
(43) Pub. Date: Oct. 1, 2026

(54) GLASS SUBSTRATE AND MANUFACTURING METHOD THEREOF

(71) Applicant: AUO Corporation, Hsinchu City (TW)

(72) Inventors: Shih-Hsiung Lin, Hsinchu City (TW); Wen-Ching Sung, Hsinchu City (TW)

(73) Assignee: AUO Corporation, Hsinchu City (TW)

(21) Appl. No.: 19/305,795

(22) Filed: Aug. 21, 2025

(30) Foreign Application Priority Data
Mar. 31, 2025 (TW) 114112338

(51) Int. Cl. C03C 23/00; C03C 15/00

(52) U.S. Cl. CPC C03C 23/0025; C03C 15/00; C03C 23/007

(57) ABSTRACT

A glass substrate including at least one first through hole and at least one second through hole is provided. The first through hole has a first diameter and a second diameter, wherein the first diameter is defined on a surface of the glass substrate and the second diameter is defined on an inner wall of the first through hole. The second through hole has a third diameter and a fourth diameter, wherein the third diameter is defined on the surface of the glass substrate and the fourth diameter is defined on an inner wall of the second through hole. A ratio of the second diameter to the first diameter is less than a ratio of the fourth diameter to the third diameter. A glass substrate manufacturing method is also provided.

### CROSS-REFERENCE TO RELATED APPLICATION

This application claims the priority benefit of Taiwan application serial no. 114112338, filed on Mar. 31, 2025. The entirety of the above-mentioned patent application is hereby incorporated by reference herein and made a part of this specification.

### BACKGROUND OF THE INVENTION

### Field of the Invention

The invention relates to a glass substrate and a manufacturing method thereof.

### Description of Related Art

Conventional techniques generally utilize acid or alkali etching to form a plurality of through holes on a glass substrate. However, the etching process is prone to the situation in which one or a plurality of predetermined sites of the glass substrate are not formed with through holes meeting requirements, resulting in a low yield issue.

### SUMMARY OF THE INVENTION

The invention provides a glass substrate and a manufacturing method thereof, in which the yield of the glass substrate is significantly improved.

According to an embodiment of the invention, a glass substrate is provided, including at least one first through hole and at least one second through hole. The first through hole has a first diameter and a second diameter, wherein the first diameter is defined on a surface of the glass substrate and the second diameter is defined on an inner wall of the first through hole. The second through hole has a third diameter and a fourth diameter, wherein the third diameter is defined on the surface of the glass substrate and the fourth diameter is defined on an inner wall of the second through hole. A ratio of the second diameter to the first diameter is less than a ratio of the fourth diameter to the third diameter.

According to an embodiment of the invention, a glass substrate manufacturing method is provided, including: etching a glass substrate to form at least one first through hole; and laser drilling the glass substrate to form at least one second through hole different from the first through hole.

Based on the above, the glass substrate manufacturing method provided by an embodiment of the invention utilizes laser to alleviate the situation in which one or a plurality of predetermined sites of the glass substrate are not formed with one or a plurality of through holes meeting requirements, thereby significantly improving the yield of the glass substrate.

In order to make the above features and advantages of the invention more clearly understood, embodiments are given below and described in detail with reference to the accompanying drawings.

### BRIEF DESCRIPTION OF THE DRAWINGS

FIG. 1A to FIG. 1E show schematic views of a glass substrate manufacturing method according to an embodiment of the invention.

FIG. 2A and FIG. 2B respectively show a schematic cross-sectional view and a three-dimensional view of a glass substrate manufactured by the steps shown in FIG. 1A to FIG. 1E.

### DESCRIPTION OF THE EMBODIMENTS

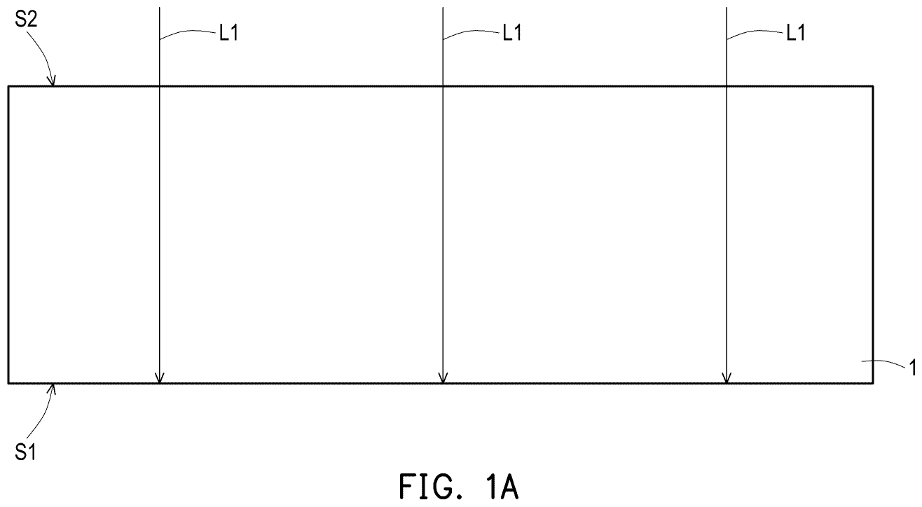

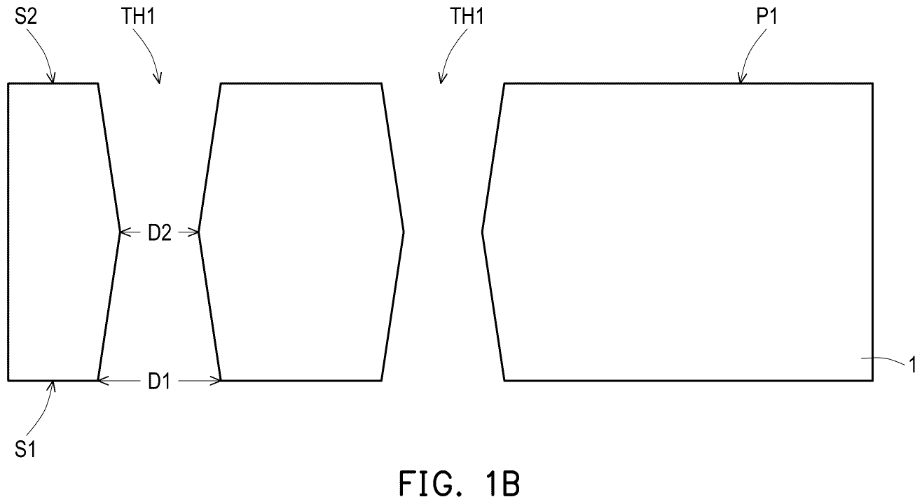

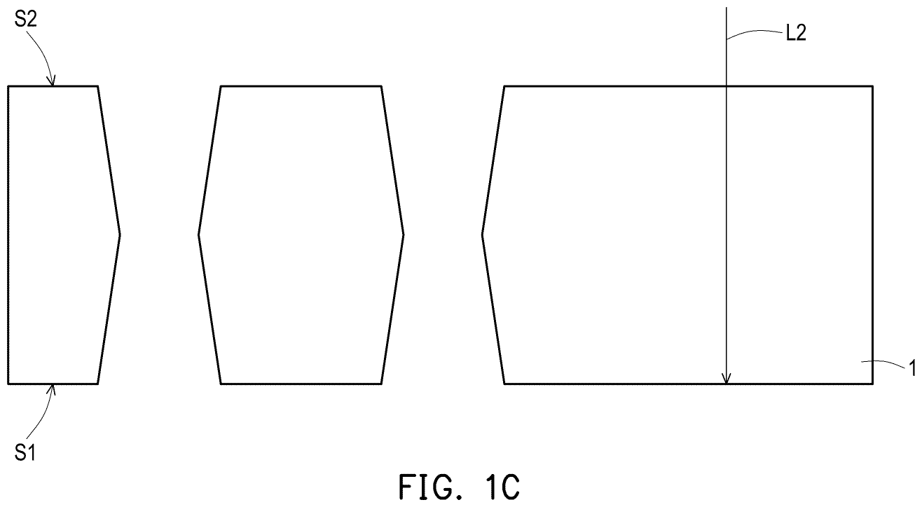

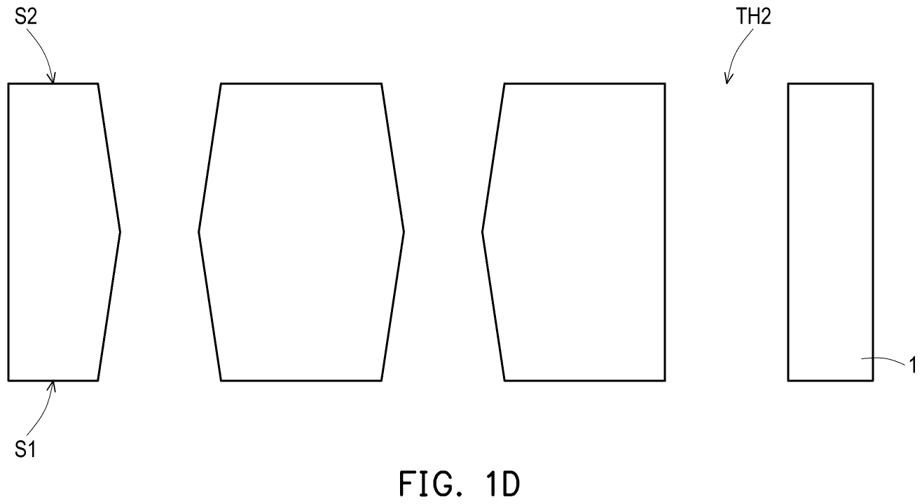

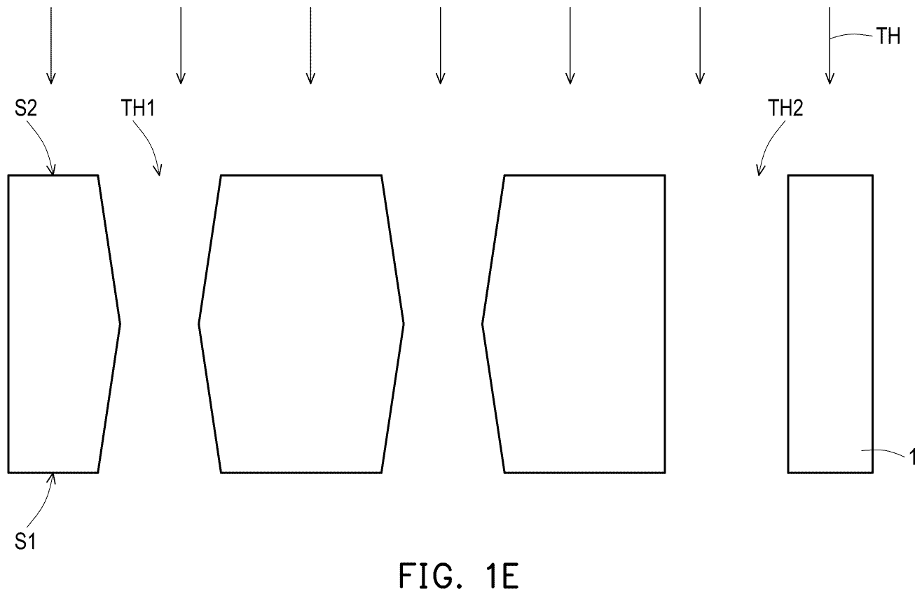

FIG. 1A to FIG. 1E show schematic views of a glass substrate manufacturing method according to an embodiment of the invention. A glass substrate manufacturing method of the present embodiment is used to manufacture a through hole on a glass substrate.

Referring to FIG. 1A, a first laser beam L1 is irradiated on a plurality of predetermined sites of a glass substrate 1 to modify the glass substrate 1. The first laser beam L1 may be, for example, a picosecond laser.

Next, the modified glass substrate 1 is etched using an acid or an alkali to form the structure shown in FIG. 1B. As shown in FIG. 1B, since the glass substrate 1 is etched via the acid or the alkali, a plurality of through holes TH1 having a waist are formed. Each of the through holes TH1 has a diameter D1 on the surface of the glass substrate 1 and a diameter D2 in the glass substrate 1, wherein the diameter D2 may be the minimum diameter defined on the inner wall of the through holes TH1.

After the step shown in FIG. 1B, the glass substrate 1 may be inspected using automated optical inspection (AOI) to confirm that the through holes TH1 meeting requirements are formed on all of a plurality of predetermined sites of the glass substrate 1, wherein the requirements may be, for example, regarding the diameter D1 and the diameter D2 of the through holes TH1, or the ratio of the two diameters D1 and D2.

In a case that any through hole on the glass substrate 1 does not meet requirements, or a through hole is not formed at any predetermined site (such as a position P1 shown in FIG. 1B), a second laser beam L2 is used to drill a hole at the position P1 (as shown in FIG. 1C) to form a through hole TH2 (as shown in FIG. 1D). The second laser beam L2 may be, for example, a femtosecond laser, but is not limited thereto.

In a case that microcracks appear on the inner wall of the through hole TH2, high temperature annealing may be performed, as shown in FIG. 1E. This high temperature annealing heats the inner wall of the through hole TH2 to the annealing temperature of glass to eliminate the microcracks on the inner wall of the through hole TH2. The resulting glass substrate 1 has through holes meeting requirements on all predetermined sites thereon, as shown in FIG. 1E.

It should be noted that the invention is not limited to using high temperature annealing to eliminate microcracks on the inner wall of the through hole TH2. In another embodiment, after the step shown in FIG. 1D, the glass substrate 1 may be micro etched using an acid or an alkali to eliminate microcracks that may appear on the inner wall of the through holes TH1, on the inner wall of the through hole TH2, and on the surface of the glass substrate 1.

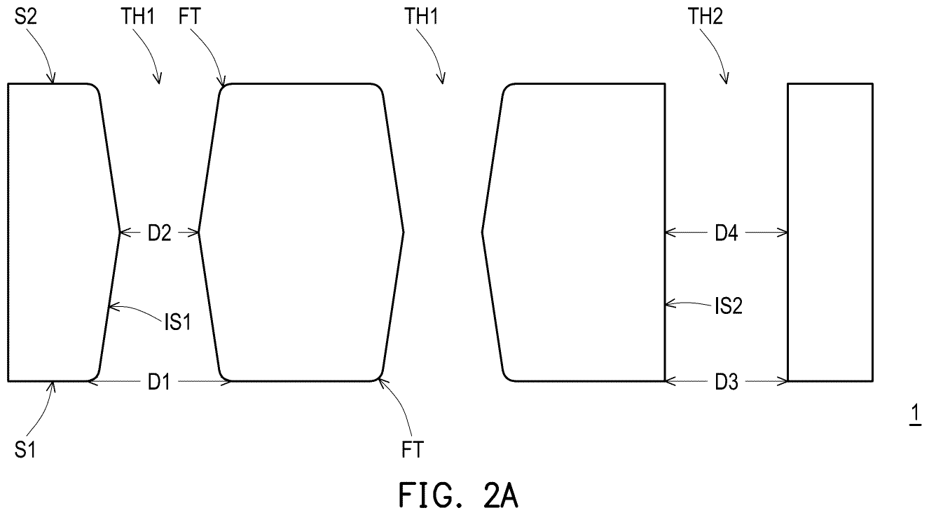

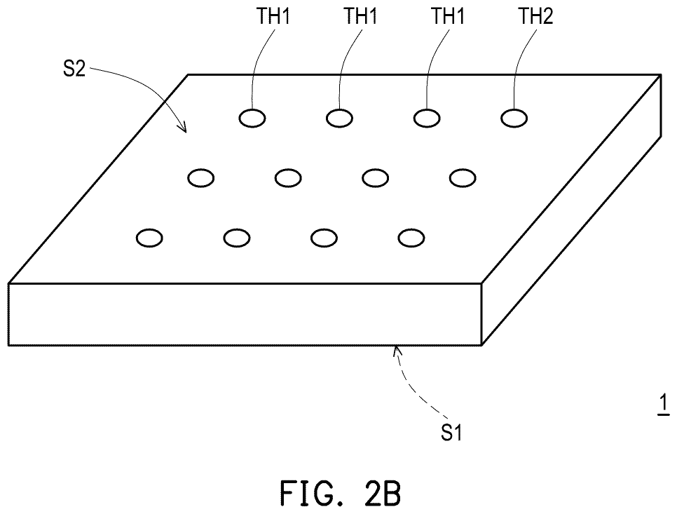

FIG. 2A and FIG. 2B respectively show a schematic cross-sectional view and a three-dimensional view of a glass substrate manufactured by the steps shown in FIG. 1A to FIG. 1E.

As shown in FIG. 2A and FIG. 2B, the glass substrate 1 includes a plurality of through holes TH1 and at least one through hole TH2. Each of the through holes TH1 has the diameter D1 and the diameter D2. The diameter D1 is defined on a surface S1 of the glass substrate 1. The diameter D2 is defined on an inner wall IS1 of the through holes TH1. Specifically, the diameter D2 is the minimum inner diameter of the through holes TH1. The through hole TH2 has a diameter D3 and a diameter D4. The diameter D3 is defined on the surface S1 of the glass substrate 1. The diameter D4 is defined on an inner wall IS2 of the through hole TH2. Specifically, the diameter D4 is the minimum inner diameter of the through hole TH2.

For each of the through holes TH1 formed via etching, the ratio of the diameter D2 to the diameter D1 is less than 1 (e.g., less than or equal to 0.9). Furthermore, a chamfer FT is formed between the surface S1 and the first inner wall IS1 and between a surface S2 and the first inner wall IS1. In the present embodiment, the chamfer FT may be, for example, arc-shaped, but is not limited thereto. In other embodiments, the chamfer FT may also be a gentle slope connecting the arc edge with the surfaces S1, S2 and the inner wall IS1. Moreover, since the through hole TH2 is formed via laser drilling, the ratio of the diameter D4 to the diameter D3 is typically greater than 0.9.

Furthermore, the roughness of the inner wall IS1 of each of the through holes TH1 formed via etching is greater than the roughness of the inner wall IS2 of the through hole TH2 formed via laser drilling. In some embodiments, the roughness (Ra) of the inner wall IS1 of the through holes TH1 is greater than 0.1 μm, and the roughness (Ra) of the inner wall IS2 of the through hole TH2 is less than 0.1 μm.

Furthermore, as shown in FIG. 1B, the surface S1 and the surface S2 of the glass substrate 1 are also etched by an acid or an alkali. Therefore, the roughness of the surface S1 and the surface S2 is greater than the roughness of the inner wall IS2 of the through hole TH2. In some embodiments, the roughness (Ra) of the surface S1 and the surface S2 is greater than 0.1 μm.

Moreover, since the through hole TH2 is formed via laser drilling to alleviate the lack of a through hole formed at the predetermined position P1 (as shown in FIG. 1C), an optical element is used to control the beam width of the second laser beam L2 so that the diameter D3 of the through hole TH2 on the surface S1 is similar to the diameter D1 of the through holes TH1 on the surface S1, so that the plurality of through holes TH1 and TH2 of the glass substrate 1 have a more consistent appearance. In some embodiments, the ratio of the difference between the diameter D1 and the diameter D3 to the diameter D1 (i.e., (D1−D3)/D1) is less than or equal to 0.1.

Based on the above, the glass substrate manufacturing method provided by an embodiment of the invention utilizes laser to alleviate the situation in which one or a plurality of predetermined sites of the glass substrate are not formed with through holes meeting requirements, thereby significantly improving the yield of the glass substrate.

What is claimed is:

1. A glass substrate, comprising:
at least one first through hole having a first diameter and a second diameter, wherein the first diameter is defined on a surface of the glass substrate and the second diameter is defined on a first inner wall of the first through hole; and
at least one second through hole having a third diameter and a fourth diameter, wherein the third diameter is defined on the surface of the glass substrate and the fourth diameter is defined on a second inner wall of the second through hole,
wherein a first ratio of the second diameter to the first diameter is less than a second ratio of the fourth diameter to the third diameter.

2. The glass substrate of claim 1, wherein the first ratio is less than or equal to 0.9.

3. The glass substrate of claim 1, wherein the second ratio is greater than 0.9.

4. The glass substrate of claim 1, wherein the first inner wall has a first roughness, the second inner wall has a second roughness, and the first roughness is greater than the second roughness.

5. The glass substrate of claim 4, wherein the first roughness is greater than 0.1 μm.

6. The glass substrate of claim 4, wherein the second roughness is less than 0.1 μm.

7. The glass substrate of claim 1, wherein the surface has a first roughness, the second inner wall has a second roughness, and the first roughness is greater than the second roughness.

8. The glass substrate of claim 7, wherein the first roughness is greater than 0.1 μm.

9. The glass substrate of claim 7, wherein the second roughness is less than 0.1 μm.

10. The glass substrate of claim 1, wherein a ratio of a difference between the first diameter and the third diameter to the first diameter is less than or equal to 0.1.

11. The glass substrate of claim 1, wherein the first through hole has a chamfer between the surface and the first inner wall.

12. A glass substrate manufacturing method, comprising:
etching a glass substrate to form at least one first through hole; and
laser drilling the glass substrate to form at least one second through hole different from the at least one first through hole.

13. The glass substrate manufacturing method of claim 12, further comprising:
performing a high temperature annealing process on the at least one second through hole.

14. The glass substrate manufacturing method of claim 12, further comprising:
micro etching the second through hole using an acid or an alkali.

15. The glass substrate manufacturing method of claim 12, further comprising:
modifying a site on the glass substrate corresponding to the second through hole via a laser.
